(19) United States
(12) Patent Application Publication
(10) Pub. No.: US 2022/0028984 A1
(43) Pub. Date: Jan. 27, 2022

(54) INTERLAYER DIELECTRIC LAYER STRUCTURE FOR POWER MOS DEVICE AND METHOD FOR MAKING THE SAME

(71) Applicant: Hua Hong Semiconductor (Wuxi) Limited, Wuxi (CN)

(72) Inventors: Xiuyong LIU, Wuxi (CN); Zhengrong CHEN, Wuxi (CN); Changming WU, Wuxi (CN); Jiliang ZHANG, Wuxi (CN); Lipei JIN, Wuxi (CN)

(73) Assignee: Hua Hong Semiconductor (Wuxi) Limited, Wuxi (CN)

(21) Appl. No.: 17/096,109

(22) Filed: Nov. 12, 2020

(51) Int. Cl. H01L 29/40; H01L 21/02

(52) U.S. Cl. CPC H01L 29/408; H01L 21/02274; H01L 21/02211; H01L 21/02164

(57) ABSTRACT

The present application relates to the field of semiconductor forming technologies, in particular to an interlayer dielectric layer structure for a power MOS device and a method for making the same. The interlayer dielectric layer structure for a power MOS device comprises a silicon-rich oxide SiOₓ film layer deposited on the surface of the power MOS device, wherein a silicon dioxide film layer is deposited on the silicon-rich oxide SiOₓ film layer. The method for forming an interlayer dielectric layer structure for a power MOS device comprises the following steps: depositing a silicon-rich oxide SiOₓ film layer on the surface of the power MOS device; and depositing a silicon dioxide film layer on the silicon-rich oxide SiOₓ film layer.

### CROSS-REFERENCE TO RELATED APPLICATION

This application claims priority to Chinese patent application No. 202010716889.9, filed at CNIPA on Jul. 23, 2020, and entitled “INTERLAYER DIELECTRIC LAYER STRUCTURE FOR POWER MOS DEVICE AND METHOD FOR MAKING THE SAME”, the disclosure of which is incorporated herein by reference in entirety.

### TECHNICAL FIELD

The present application relates to the field of semiconductor technologies, in particular to an interlayer dielectric layer structure for a power MOS device and a method for making the same.

### BACKGROUND

With the development of integrated circuit process technologies, the size of integrated circuits is continuously reduced in accordance with Moore's Law, in which case process technologies need to be continuously improved to support the ever-increasing product requirement. With the improvement of the IC process technologies, the 12-inch production line begins to produce power MOS devices.

In the related art, a silicon dioxide interlayer dielectric film is usually formed between a power MOS device and a first metal layer, to achieve the effect of isolating and insulating the device. However, for a power MOS device with medium or high voltage power, the back-end process for an interlayer dielectric film thereof generates a large number of movable ions, and these movable ions can pass through the silicon dioxide interlayer dielectric film and enter the channel of the power MOS device, thereby causing the problem of a relatively large electric leakage of the power MOS device, and affecting the product performance and the production of the power MOS device in a 12-inch process.

### BRIEF SUMMARY

The present application provides an interlayer dielectric layer structure for a power MOS device and a method for making the same, to solve the problem of a relatively large electric leakage of the power MOS device resulting from movable ions passing through a silicon dioxide interlayer dielectric film and entering a channel in the related art.

In one aspect, according to some embodiments in this application, an interlayer dielectric layer structure for a power MOS device, including a silicon-rich oxide SiOₓ film layer deposited on the surface of the power MOS device, wherein a silicon dioxide film layer is deposited on the silicon-rich oxide SiOₓ film layer.

In some cases, the refractive index of the silicon-rich oxide SiOₓ film layer is 1.5 to 1.65.

In some cases, the ratio of the number of silicon atoms to the number of oxygen atoms in the silicon-rich oxide is greater than 0 and less than ½.

In another aspect, according to some embodiments in this application, a method for forming an interlayer dielectric layer structure for a power MOS device, including the following steps: depositing a silicon-rich oxide SiOₓ film layer on the surface of the power MOS device; and depositing a silicon dioxide film layer on the silicon-rich oxide SiOₓ film layer.

In some cases, the step of depositing a silicon-rich oxide SiOₓ film layer on the surface of the power MOS device comprises: depositing the silicon-rich oxide SiOₓ film layer on the surface of the power MOS device by means of a plasma enhanced chemical vapor deposition process using silane SiH₄ and nitrous oxide N₂O as reactive raw materials, wherein a reaction formula is as follows: SiH₄+N₂O→SiOₓ+H₂+H₂O+volatile sub stance.

In some cases, the refractive index of the silicon-rich oxide SiOₓ film layer is 1.5 to 1.65.

In some cases, the thickness of the silicon-rich oxide SiOₓ film layer is less than 6000 A.

The technical solution of the present application comprises at least the following advantage: an interlayer dielectric layer structure containing silicon-rich oxide SiOₓ film layer is used as an isolation layer between a metal layer and a lower layer device; relative to the silicon dioxide SiO₂, the proportion of silicon atoms in the silicon-rich oxide SiOₓ is increased; since the increased silicon atoms have dangling bonds, generated movable ions can bind to the silicon atoms due to an electrostatic effect in a subsequent process or environment, thereby preventing the movable ions from passing through the interlayer dielectric layer and reducing a source-drain leakage current.

### BRIEF DESCRIPTION OF THE DRAWINGS

In order to more clearly explain the specific implementations of the present application or the technical solutions in the prior art, the drawings required in description of the specific implementations or the prior art will be briefly described below. It is obvious that the drawings described below are some implementations of the present application, and one skilled in the art could also obtain other drawings on the basis of these drawings without contributing any inventive labor.

FIG. 1 illustrates an interlayer dielectric layer structure provided in embodiments of the present application.

FIG. 2 illustrates a power MOS device including the interlayer dielectric layer structure shown in FIG. 1.

FIG. 3 illustrates a flowchart of a method for forming an interlayer dielectric layer structure for a power MOS device provided in the embodiments of the present application.

FIG. 4 illustrates a distribution diagram of a leakage current between a drain and a source of an 80 V power MOS device including the interlayer dielectric layer structure provided in the embodiments of the present application.

FIG. 5 illustrates a distribution diagram of a leakage current between a drain and a source of a 120 V power MOS device including the interlayer dielectric layer structure provided in the embodiments of the present application.

### DETAILED DESCRIPTION OF THE DISCLOSURE

The technical solution of the present application will be clearly and completely described below with reference to the drawings. Obviously, the described embodiments are part of the embodiments of the present application, instead of all of them. Based on the embodiments in the present application, all other embodiments obtained by one skilled in the art without contributing any inventive labor shall fall into the protection scope of the present application.

In the description of the present application, it should be noted that the orientation or position relationship indicated by the terms “center”, “upper”, “lower”, “left”, “right”, “vertical”, “horizontal”, “inner”, “outer”, etc. is based on the orientation or position relationship shown in the drawings, intended only for the convenience of describing the present application and simplifying the description, rather than indicating or implying that the apparatus or element referred to necessarily has a specific orientation or is configured or operated in a specific orientation, and thus cannot be construed as a limitation on the present application. In addition, the terms “first”, “second”, and “third” are used for descriptive purposes only and cannot be construed as indicating or implying relative importance.

In the description of the present application, it should be noted that, unless otherwise clearly specified and limited, the terms “mounting”, “coupling”, and “connecting” should be understood in a broad sense, for example, a connection can be a fixed connection, a detachable connection, or an integrated connection, can be a mechanical connection or an electrical connection, can be a direct connection, an indirect connection implemented by means of an intermedium, or an internal connection between two components, and can be a wireless connection or a wired connection. One skilled in the art could understand the specific meanings of the above terms in the present application on the basis of specific situations.

In addition, the technical features involved in different embodiments of the present application described below can be combined with each other in the case of no conflict.

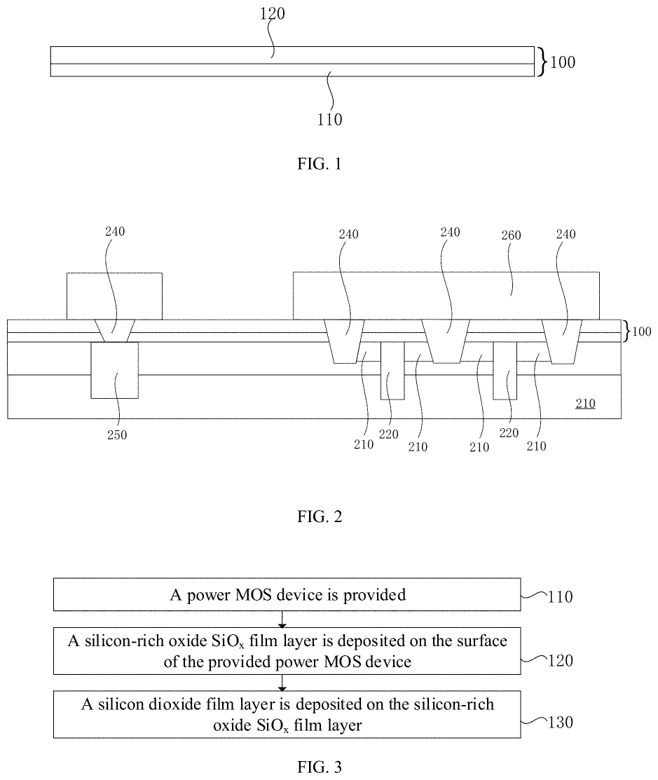

Referring to FIG. 1, which illustrates an interlayer dielectric layer structure, the interlayer dielectric layer structure 100 includes a silicon-rich oxide (SiOₓ, 0<x<2) film layer 110, wherein a silicon dioxide film layer 120 is deposited on the silicon-rich oxide SiOₓ film layer.

The ratio of the number of silicon atoms to the number of oxygen atoms in the silicon-rich oxide SiOₓ film layer 110 is greater than 0 and less than ½, while the ratio of the number of silicon atoms to the number of oxygen atoms in silicon dioxide SiO₂ is equal to ½, so relative to the silicon dioxide SiO₂, the proportion of silicon atoms in the silicon-rich oxide SiOₓ is increased; since the increased silicon atoms have dangling bonds, generated movable ions can bind to the silicon atoms due to an electrostatic effect in a subsequent process or environment, thereby preventing the movable ions from passing through the interlayer dielectric layer.

Referring to FIG. 2, which illustrates a power MOS device including the interlayer dielectric layer structure shown in FIG. 1, the power MOS device includes the following: an epitaxial layer 210 formed on a semiconductor substrate layer.

Source regions 220 spaced from each other are formed in the epitaxial layer 210.

The adjacent source regions 220 are isolated from each by means of a shielding gate 230.

The interlayer dielectric layer structure shown in FIG. 1 is deposited on the power MOS device, and the interlayer dielectric layer structure deposited on the power MOS device is provided with a contact hole 240. The contact hole 240 extends from an upper surface of the interlayer dielectric layer 100 downward to contact a gate 250 and the source region 220 of the power MOS device, and the contact hole 240 is filled with conductive metal.

A metal lead wire layer 260 is disposed on the interlayer dielectric layer 100 at the position where the contact hole 240 is located, and the contact hole 240 extends upward to contact the metal lead wire layer 260.

In the embodiment, an interlayer dielectric layer structure containing silicon-rich oxide SiOₓ is used as an isolation layer between a metal lead wire layer and a lower layer device; the ratio of the number of silicon atoms to the number of oxygen atoms in the silicon-rich oxide SiOₓ film layer is greater than 0 and less than ½, while the ratio of the number of silicon atoms to the number of oxygen atoms in silicon dioxide SiO₂ is equal to ½, so relative to the silicon dioxide SiO₂, the proportion of silicon atoms in the silicon-rich oxide SiOₓ is increased; since the increased silicon atoms have dangling bonds, generated movable ions can bind to the silicon atoms due to an electrostatic effect in a subsequent process or environment, thereby preventing the movable ions from passing through the interlayer dielectric layer and avoiding the problem of a relatively large electric leakage.

Referring to FIG. 3, which illustrates a flowchart of a method for forming an interlayer dielectric layer structure for a power MOS device, the method for forming an interlayer dielectric layer structure for a power MOS device includes the following step.

Step S110: A power MOS device is provided.

The provided power MOS device is shown in FIG. 2 and includes an epitaxial layer formed on a semiconductor substrate layer, wherein source regions spaced from each other are formed in the epitaxial layer, and the adjacent source regions are isolated from each by means of a shielding gate. The interlayer dielectric layer structure shown in FIG. 1 is deposited on the power MOS device, and the interlayer dielectric layer structure deposited on the power MOS device is provided with a contact hole. The contact hole extends from an upper surface of the interlayer dielectric layer downward to contact a gate and the source region of the power MOS device, and the contact hole is filled with conductive metal. A metal lead wire layer is disposed on the interlayer dielectric layer at the position where the contact hole is located, and the contact hole extends upward to contact the metal lead wire layer.

Step S120: A silicon-rich oxide SiOₓ film layer is deposited on the surface of the provided power MOS device.

The deposition of the silicon-rich oxide SiOₓ film layer can be implemented by means of the following step: the silicon-rich oxide SiOₓ film layer is deposited on the surface of the power MOS device by means of a plasma enhanced chemical vapor deposition process using silane SiH₄ and nitrous oxide N₂O as reactive raw materials, wherein a reaction formula is as follows: SiH₄+N₂O→SiOₓ+H₂+H₂O+volatile substance.

The above reaction can be implemented by means of the following steps: an argon gas is added into a reaction chamber, the power MOS device is placed in the reaction chamber, and then, a nitrous oxide N₂O gas and a silane SiH₄ gas are added into the reaction chamber, such that the reaction chamber is in a specific pressure environment and a radio frequency environment, wherein the argon gas forms an argon plasma in this radio frequency environment, argon ions in the argon plasma can bombard atoms from the nitrous oxide N₂O gas and the silane SiH₄ gas, the atoms bombarded out can react with each other in a specific temperature environment to generate the silicon-rich oxide SiOₓ, and the silicon-rich oxide SiOₓ is deposited on the surface of the power MOS device to form the silicon-rich oxide SiOₓ film layer.

The refractive index of the silicon-rich oxide SiOₓ prepared by means of the above method is 1.5 to 1.65, wherein the refractive index reflects the proportion of silicon atoms in the silicon-rich oxide SiOₓ.

Optionally, the thickness of the silicon-rich oxide SiOₓ film layer is less than 6000 A.

Step S130: A silicon dioxide film layer is deposited on the silicon-rich oxide SiOₓ film layer.

For the above-mentioned silicon-rich oxide SiOₓ, x can be greater than 0 and less than 2, so that the ratio of the number of silicon atoms to the number of oxygen atoms in the silicon-rich oxide SiOₓ film layer 110 is greater than 0 and less than ½. In addition, the silicon-rich oxide can be Si_{y}O₂, wherein y>1.

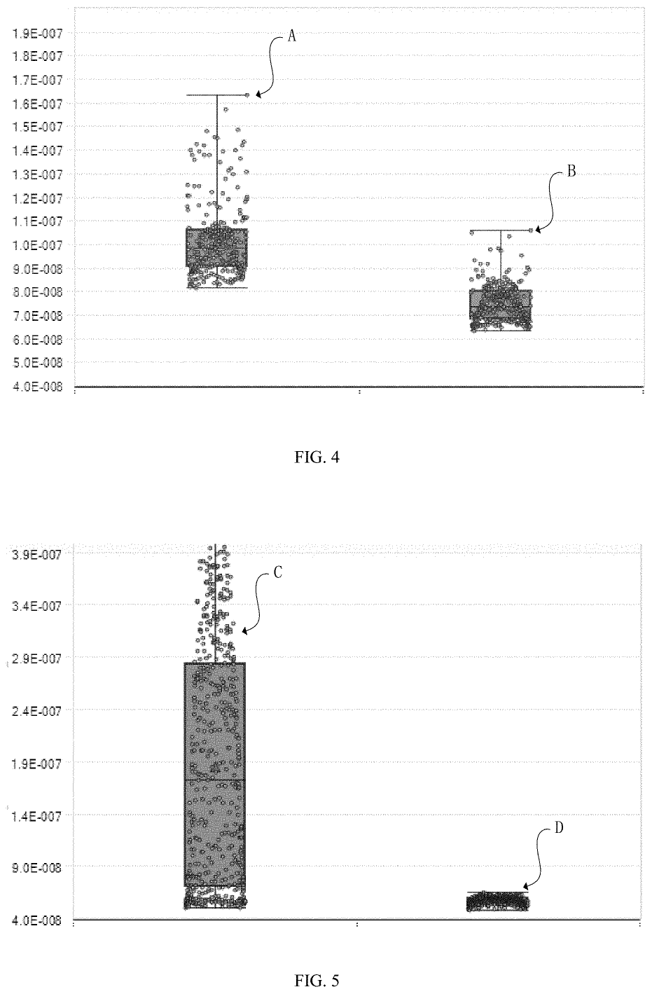

A leakage current between a drain and a source of several medium and high voltage power MOS devices in the related art and medium and high voltage power MOS devices including the interlayer dielectric layer structure provided in the embodiment of the present application are tested separately. In the test, the medium and high voltage power MOS devices including the interlayer dielectric layer structure provided in the embodiment of the present application serve as an experimental group, and the medium and high voltage power MOS devices in the related art serve as a control group, to measure the distribution of the leakage current between the drain and the source of each of the medium and high voltage power MOS devices and obtain the distribution diagrams shown in FIGS. 4 and 5.

FIG. 4 illustrates a comparative distribution diagram of leakage currents between the drain and the source of an 80 V power MOS device in the related art and of an 80 V power MOS device including the interlayer dielectric layer structure provided in the embodiment of the present application. FIG. 5 illustrates a comparative distribution diagram of leakage currents between the drain and the source of a 120 V power MOS device in the related art and of a 120 power MOS device including the interlayer dielectric layer structure provided in the embodiment of the present application.

Referring to FIG. 4, the serial number A represents a distribution diagram of the leakage current between the drain and the source of the 80 V power MOS device in the related art, and the serial number B represents a distribution diagram of the leakage current between the drain and the source of the 80 V power MOS device including the interlayer dielectric layer structure provided in the embodiment of the present application. It can be seen from the distribution diagram represented by the serial number A that the leakage current between the drain and source of the 80 V power MOS device in the related art is distributed in the range of 8.1E-008 to 1.6E-007, i.e., 8.1×10-8 to 1.6×10⁻⁷, with an average value of 1.0E-007, i.e., 1.0×10⁻⁷. It can be seen from the distribution diagram represented by the serial number B that the leakage current between the drain and the source of the 80 V power MOS device including the interlayer dielectric layer structure provided in the embodiment of the present application is distributed in the range of 6.2E-008 to 1.0E-007, i.e., 6.2×10⁻⁸ to 1.0×10⁻⁷, with an average value of 7.4E-008, i.e., 7.4×10⁻⁸.

It can be seen from FIG. 4 that, relative to the leakage current between the drain and source of the 80 V power MOS device in the related art, the leakage current between the drain and the source of the 80 V power MOS device including the interlayer dielectric layer structure provided in the embodiment of the present application is reduced.

Referring to FIG. 5, the serial number C represents a distribution diagram of the leakage current between the drain and the source of the 120 V power MOS device in the related art, and the serial number D represents a distribution diagram of the leakage current between the drain and the source of the 120 V power MOS device including the interlayer dielectric layer structure provided in the embodiment of the present application. It can be seen from the distribution diagram represented by the serial number C that the leakage current between the drain and source of the 120 V power MOS device in the related art is distributed in the range of 5.6E-008 to 4.0E-007, i.e., 5.6×10⁻⁸ to 4.0×10⁻⁷, with an average value of 3.8E-007, i.e., 3.8×10⁻⁷. It can be seen from the distribution diagram represented by the serial number D that the leakage current between the drain and the source of the 120 V power MOS device including the interlayer dielectric layer structure provided in the embodiment of the present application is distributed in the range of 5.6E-008 to 7.0E-007, i.e., 5.6×10⁻⁸ to 7.0×10⁻⁸, with an average value of 5.7E-008, i.e., 5.7×10⁻⁸.

It can be seen from FIG. 5 that, relative to the leakage current between the drain and source of the 120 V power MOS device in the related art, the leakage current between the drain and the source of the 120 V power MOS device including the interlayer dielectric layer structure provided in the embodiment of the present application is reduced.

In the embodiment, a power MOS device is provided, a silicon-rich oxide SiOₓ film layer is deposited on the surface of the power MOS device, a silicon dioxide film layer is deposited on the silicon-rich oxide SiOₓ film layer, and an interlayer dielectric layer structure containing silicon-rich oxide SiOₓ is used as an isolation layer between a metal layer and a lower layer device; the ratio of the number of silicon atoms to the number of oxygen atoms in the silicon-rich oxide SiOₓ film layer is greater than 0 and less than ½, while the ratio of the number of silicon atoms to the number of oxygen atoms in silicon dioxide SiO₂ is equal to ½, so relative to the silicon dioxide SiO₂, the proportion of silicon atoms in the silicon-rich oxide SiOₓ is increased; since the increased silicon atoms have dangling bonds, generated movable ions can bind to the silicon atoms due to an electrostatic effect in a subsequent process or environment, thereby preventing the movable ions from passing through the interlayer dielectric layer and reducing a source-drain leakage current.

Obviously, the above embodiments are merely examples used for clear description, rather than for limitation on the implementations. One skilled in the art could also make other changes or modifications in different forms on the basis of the above description. There is no need and way to exhaustively list all of the implementations herein, but obvious changes or modifications derived herefrom still fall within the protection scope created by the present application.

What is claimed is:

1. An interlayer dielectric layer structure for a power MOS device, including a silicon-rich oxide SiOₓ film layer deposited on the surface of the power MOS device, wherein a silicon dioxide film layer is deposited on the silicon-rich oxide SiOₓ film layer.

2. The interlayer dielectric layer structure for a power MOS device according to claim 1, wherein the refractive index of the silicon-rich oxide SiOₓ film layer is 1.5 to 1.65.

3. The interlayer dielectric layer structure for a power MOS device according to claim 1, wherein the ratio of the number of silicon atoms to the number of oxygen atoms in the silicon-rich oxide is greater than 0 and less than ½.

4. A method for forming an interlayer dielectric layer structure for a power MOS device, including the following steps:
depositing a silicon-rich oxide SiOₓ film layer on the surface of the power MOS device; and
depositing a silicon dioxide film layer on the silicon-rich oxide SiOₓ film layer.

5. The method for forming an interlayer dielectric layer structure for a power MOS device according to claim 4, wherein the step of depositing a silicon-rich oxide SiOₓ film layer on the surface of the power MOS device comprises:
depositing the silicon-rich oxide SiOₓ film layer on the surface of the power MOS device by means of a plasma enhanced chemical vapor deposition process using silane SiH₄ and nitrous oxide N₂O as reactive raw materials, wherein a reaction formula is as follows:
SiH₄+N₂O→SiOₓ+H₂+H₂O+volatile substance.

6. The method for forming an interlayer dielectric layer structure for a power MOS device according to claim 4, wherein the refractive index of the silicon-rich oxide SiOₓ film layer is 1.5 to 1.65.

7. The method for forming an interlayer dielectric layer structure for a power MOS device according to claim 4, wherein the thickness of the silicon-rich oxide SiOₓ film layer is less than 6000 A.
